(19) United States
(12) Patent Application Publication
(10) Pub. No.: US 2024/0334757 A1
(43) Pub. Date: Oct. 3, 2024

(54) DISPLAY DEVICE AND METHOD OF REPAIRING THE SAME

(71) Applicant: Samsung Display Co., LTD., Yongin-si (KR)

(72) Inventors: JONGBUM CHOI, Yongin-si (KR); YEEUN KANG, Yongin-si (KR); SEUL-KI KIM, Yongin-si (KR); SEUNGRAE KIM, Yongin-si (KR); WOOGEUN LEE, Yongin-si (KR); JAEHYUN LEE, Yongin-si (KR)

(21) Appl. No.: 18/620,850

(22) Filed: Mar. 28, 2024

(30) Foreign Application Priority Data
Apr. 3, 2023 (KR) 10-2023-0043687

(51) Int. Cl. H10K 59/124; H10K 59/12; H10K 71/00

(52) U.S. Cl. CPC H10K 59/124; H10K 59/1201; H10K 71/861

(57) ABSTRACT

A display device includes: a substrate including a pixel area and an array test area spaced apart from the pixel area; a gate electrode on the substrate, overlapping the pixel area, and defining a first opening; a passivation layer on the gate electrode and defining a second opening overlapping the first opening; a via insulating layer on the passivation layer and defining a third opening overlapping the second opening; a first electrode on the passivation layer and overlapping a portion of the pixel area; and an insulating layer filling the first opening.

### CROSS-REFERENCE TO RELATED APPLICATION

The present application claims priority to and the benefit of Korean Patent Application No. 10-2023-0043687, filed on Apr. 3, 2023, in the Korean Intellectual Property Office, the entire disclosure of which is incorporated herein by reference.

### BACKGROUND

### 1. Field

Aspects of some embodiments relate to a display device and a method of repairing the same.

### 2. Description of the Related Art

A display device is a device that displays images for providing visual information to a user. Among display devices, an organic light emitting diode display has recently attracted attention.

Defects may occur in some pixels during the manufacturing process of the display device. An array test may be performed to detect pixels in which the defect has occurred.

The above information disclosed in this Background section is only for enhancement of understanding of the background and therefore the information discussed in this Background section does not necessarily constitute prior art.

### SUMMARY

Aspects of some embodiments include a display device with relatively improved display quality.

Aspects of some embodiments include a method of repairing the display device.

A display device according to some embodiments includes a substrate including a pixel area and an array test area spaced apart from the pixel area, a gate electrode on the substrate, overlapping the pixel area, and defining a first opening, a passivation layer on the gate electrode and defining a second opening overlapping the first opening, a via insulating layer on the passivation layer and defining a third opening overlapping the second opening, a first electrode on the passivation layer and overlapping a portion of the pixel area, and an insulating layer filling the first opening.

According to some embodiments, the insulating layer may further fill at least a portion of the second opening.

According to some embodiments, the insulating layer may further fill the second opening and at least a portion of and the third opening.

According to some embodiments, the display device may further include a pixel defining layer covering side portions of the first electrode and exposing an upper surface of the first electrode.

According to some embodiments, the insulating layer and the pixel defining layer may include same material.

According to some embodiments, the insulating layer and the pixel defining layer may include an organic material.

According to some embodiments, the display device may further include an active pattern between the substrate and the gate electrode.

According to some embodiments, the active pattern may define a fourth opening overlapping the first opening and the insulating layer may further fill the fourth opening.

According to some embodiments, the display device may further include an array test pad on the substrate and overlapping the array test area.

According to some embodiments, the passivation layer may define a fifth opening overlapping the array test area.

According to some embodiments, the via insulating layer may define a sixth opening overlapping the fifth opening.

According to some embodiments, a portion of the upper surface of the array test pad may be exposed through the fifth opening and the sixth opening.

According to some embodiments, the first electrode may define a seventh opening overlapping the third opening.

According to some embodiments, the display device may further include a light emitting layer on the first electrode and the insulating layer and a second electrode on the light emitting layer.

According to some embodiments, the display device may further include a light blocking layer between the substrate and the gate electrode.

According to some embodiments, the light blocking layer may be connected to the gate electrode.

According to some embodiments, the display device may further include a third electrode between the substrate and the gate electrode, spaced apart from the light blocking layer in a first direction, and connected to the gate electrode.

A method of repairing a display device according to some embodiments includes forming an active pattern on a substrate and overlapping a portion of a pixel area, forming a gate electrode on the active pattern and overlapping the pixel area and an array test pad spaced apart from the gate electrode in a first direction, forming a preliminary passivation layer on the gate electrode and the array test pad, forming a preliminary via insulating layer on the preliminary passivation layer, forming a via insulating layer defining a first contact portion overlapping a portion of the pixel area and a first cutout portion overlapping the array test area by removing a portion of the preliminary via insulating layer, forming a passivation layer defining a second contact portion overlapping the first contact portion and a second cutout portion overlapping the first cutout portion by removing a portion of the preliminary passivation layer, contacting a probe pin with the array test pad, forming a through-hole penetrating the via insulating layer, the passivation layer, and the gate electrode, and forming an insulating layer filling at least a portion of the through-hole.

According to some embodiments, the first cutout portion and the second cutout portion may expose an upper surface of the array test pad.

According to some embodiments, the method may further include forming a first electrode on the via insulating layer and overlapping a portion of the pixel area after the contacting the probe pin with the array test pad before the forming the through-hole penetrating the via insulating layer, the passivation layer, and the gate electrode.

According to some embodiments, the first electrode and the gate electrode may be connected through the first contact portion and the second contact portion.

According to some embodiments, the method may further include forming a pixel defining layer covering side portions of the first electrode and exposing an upper surface of the first electrode after the forming the through-hole penetrating the via insulating layer, the passivation layer, and the gate electrode.

According to some embodiments, the forming an insulating layer filling at least a portion of the through-hole may be performed simultaneously with the forming the pixel defining layer.

According to some embodiments, the forming the through-hole may further include penetrating the first electrode.

A display device according to some embodiments includes a substrate including a pixel area and an array test area spaced apart from the pixel area, a gate electrode on the substrate, overlapping the pixel area, and defining a first opening, a passivation layer on the gate electrode and defining a second opening overlapping the first opening, a via insulating layer on the passivation layer and defining a third opening overlapping the second opening, a first electrode on the passivation layer and overlapping a portion of the pixel area, and an insulating layer filling the first opening.

That is, a through-hole may be formed in some electrodes such as gate electrode through a repair process. An insulating layer such as a pixel defining layer may fill the through-hole. Accordingly, the insulating layer may prevent or reduce instances of a short circuit between the electrode in which the through-hole is formed and a common electrode.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to some embodiments.

FIG. 2 is a circuit diagram illustrating a pixel area included in the display device of FIG. 1 according to some embodiments.

FIG. 3 is a cross-sectional view of the display device of FIG. 1 cut along a line I-I′ according to some embodiments.

FIG. 4 is a cross-sectional view illustrating a display device according to some embodiments.

FIG. 5 is a cross-sectional view illustrating a display device according to some embodiments.

FIGS. 6, 7, 8, 9, 10, 11, 12, 13, 14, 15, and 16 are cross-sectional views illustrating a method of repairing a display device according to some embodiments.

FIGS. 17, 18, and 19 are cross-sectional views illustrating a method of repairing a display device according to some embodiments.

### DETAILED DESCRIPTION

Hereinafter, aspects of a display devices according to some embodiments will be described in more detail with reference to the accompanying drawings. The same reference numerals are used for the same components in the drawings, and redundant descriptions of the same components may be omitted.

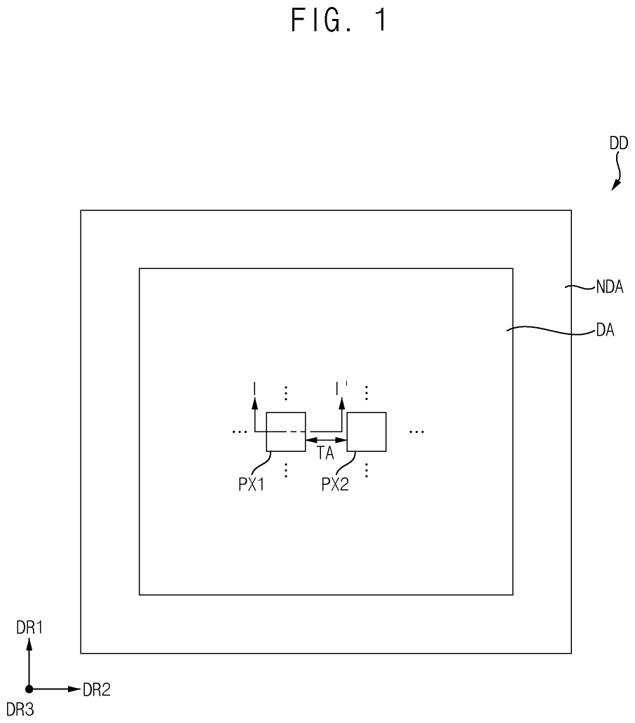

FIG. 1 is a schematic plan view illustrating a display device according to some embodiments.

Referring to FIG. 1, a display device DD according to some embodiments may include a display area DA and a non-display area NDA. The display area DA may be defined as an area capable of generating light or displaying images by adjusting transmittance of light provided from an external light source. The non-display area NDA may be an area that does not display images. In addition, the non-display area NDA may surround at least a portion of the display area DA. That is, according to some embodiments, the non-display area NDA may be in a periphery or outside a footprint of the display area DA.

A plurality of pixel areas may be located in the display area DA. Each of the plurality of pixel areas may emit light. For example. The first pixel area PX1 may emit light. The plurality of pixel areas may be repeatedly arranged along a first direction DR1 and a second direction DR2 intersecting the first direction DR1. For example, the second pixel area PX2 may be spaced apart from the first pixel area PX1 in the first direction DR1.

An array test area TA may be located between the first pixel area PX1 and the second pixel area PX2. For example, the array test area TA may be spaced apart from the first pixel area PX1 in the first direction DR1.

A driver may be located in the non-display area NDA. The driver may provide a signal or a voltage to the plurality of pixel areas. For example, the driver may include a data driver, a gate driver, or the like.

The first direction DR1 and the second direction DR2 intersecting the first direction DR1 may be defined. In addition, a third direction DR3 perpendicular to a plane formed by the first direction DR1 and the second direction DR2 may be defined.

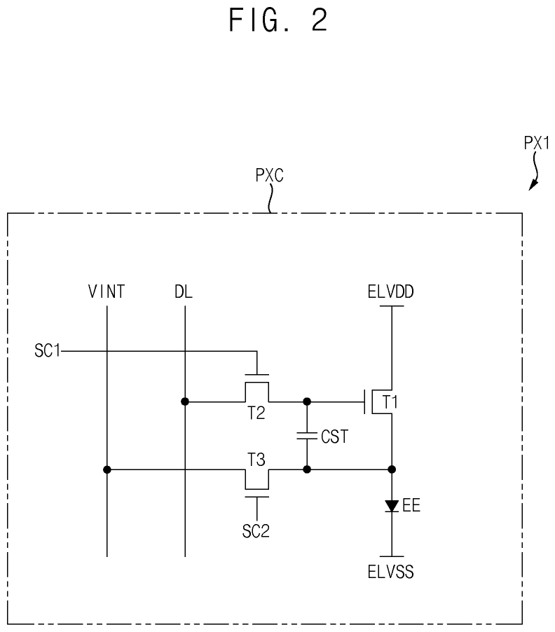

FIG. 2 is a schematic circuit diagram illustrating a pixel area included in the display device of FIG. 1.

Referring to FIG. 2, the first pixel area PX1 may include a pixel circuit PXC. The pixel circuit PXC may include a light emitting element EE, a first transistor T1, a second transistor T2, a third transistor T3, and a storage capacitor CST.

The first transistor T1 may include a gate electrode, a first electrode, and a second electrode. The gate electrode of the first transistor T1 may be connected to a second electrode of the second transistor T2. In addition, a first power supply voltage ELVDD may be applied to the first electrode of the first transistor T1. In addition, the second electrode of the first transistor T1 may be connected to a first electrode of the light emitting element EE. Accordingly, the first transistor T1 may apply a driving current to the light emitting element EE. That is, the first transistor T1 may be a driving transistor.

The second transistor T2 may include a gate electrode, a first electrode, and

a second electrode. The gate electrode of the second transistor T2 may be connected to a first scan line SC1. In addition, the first electrode of the second transistor T2 may be connected to a data line DL. In addition, the second electrode of the second transistor T2 may be connected to the gate electrode of the first transistor T1. Accordingly, the second transistor T2 may transmit a data signal applied from the data line DT to the gate electrode of the first transistor T1 according to a scan signal applied from the first scan line SC1. That is, the second transistor T2 may be a switching transistor.

The third transistor T3 may include a gate electrode, a first electrode, and a second electrode. The gate electrode of the third transistor T3 may be connected to a second scan line SC2. In addition, the first electrode of the third transistor T3 may be connected to a initialization voltage line VINT. In addition, the second electrode of the third transistor T3 may be connected to the first electrode of the light emitting element EE and the second electrode of the first transistor T1. Accordingly, the third transistor T3 may transmit an initialization voltage applied from the initialization voltage line VINT to the first electrode of the light emitting element EE according to a scan signal applied from the second scan line SC2. That is, the third transistor T3 may be a sensing transistor.

The light emitting element EE may include a first electrode and a second electrode. The second electrode of the light emitting element EE may be connected to a second power supply voltage ELVSS. For example, the second power supply voltage ELVSS may be a low power supply voltage, and the first power supply voltage ELVDD may be a high power supply voltage.

The storage capacitor CST may be connected between the second electrode of the first transistor T1 and the gate electrode of the first transistor T1. Accordingly, the storage capacitor CST may play a role of maintaining a constant data voltage applied to the gate electrode of the first transistor T1.

FIG. 2 may illustrate an example in which the pixel circuit PXC includes the first transistor T1, the second transistor T2, third transistor T3, and a storage capacitor CST. Embodiments according to the present disclosure are not limited thereto, however.

FIG. 2 may illustrate an example in which the pixel circuit PXC includes the first transistor T1, the second transistor T2, the third transistor T3, and the storage capacitor CST. That is, FIG. 2 may illustrate an example in which the pixel circuit PXC includes a 3T1C (3Transistor-1Capacitor) structure. However, embodiments according to the present disclosure are not limited thereto, and the pixel circuit PXC may include other structures such as a 2T1C structure, a 7T1C structure, and a 6T1C structure, and the like. For example, according to some embodiments, the pixel circuit PXC may include additional components or fewer components than what is illustrated in FIG. 2, without departing from the spirit and scope of embodiments according to the present disclosure.

In addition, FIG. 2 may illustrate the pixel circuit PXC included in the first pixel area PX1. However, embodiments according to the present disclosure are not limited thereto, and the second pixel area PX2 may also include the pixel circuit PXC of FIG. 2.

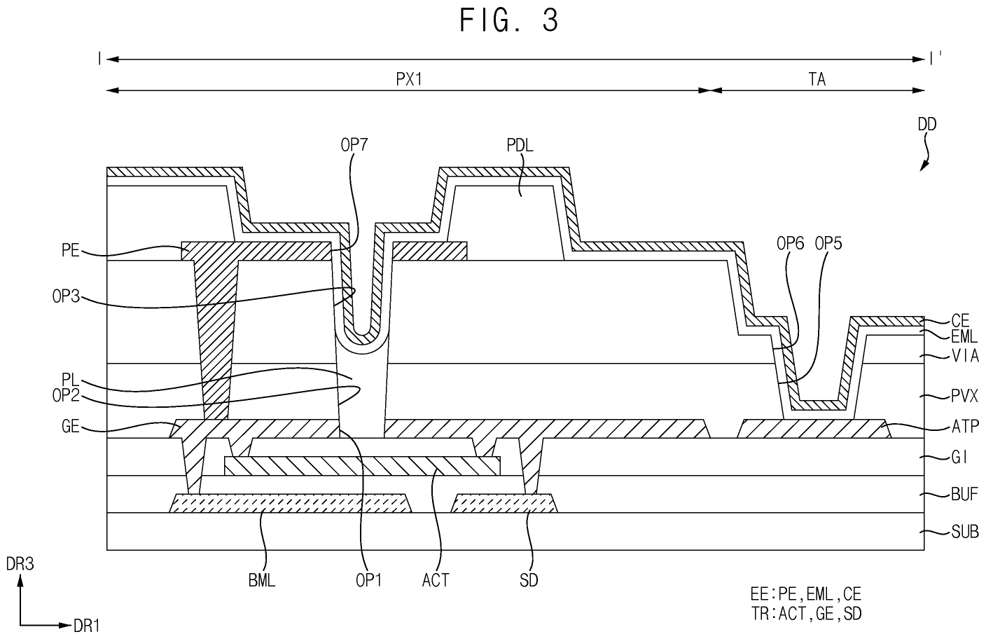

FIG. 3 is a schematic cross-sectional view of the display device of FIG. 1 cut along a line I-I′.

Referring to FIG. 3, the display device DD according to some embodiments may include a substrate SUB, a buffer layer BUF, a light blocking layer BML, a source electrode SD, a gate insulating layer GI, an active pattern ACT, a gate electrode GE, an array test pad ATP, a passivation layer PVX, a via insulating layer VIA, a pixel electrode PE, an insulating layer PL, a light emitting layer EML, a common electrode CE, and a pixel defining layer PDL.

The light emitting element EE may include the pixel electrode PE, the light emitting layer EML, and the common electrode CE. In addition, the transistor TR may include the active pattern ACT, the gate electrode GE, and the source electrode SD.

The substrate SUB may include a transparent material or an opaque material. The substrate SUB may be formed of a transparent resin substrate. Example of the transparent resin substrate may include a polyimide substrate. In this case, the polyimide substrate may include a first organic layer, a first barrier layer, a second organic layer, and the like.

Alternatively, the substrate SUB may include a quartz substrate, a synthetic quartz substrate, a calcium fluoride substrate, a fluorine-doped quartz substrate, a sodalime glass substrate, a non-alkali glass substrate, and the like. These materials may be used alone or in combination with each other.

The light blocking layer BML may be located on the substrate SUB. For example, the light blocking layer BML may overlap a portion of the first pixel area PX1. The light blocking layer BML may prevent or reduce instances of external light being incident. Accordingly, the light blocking layer BML may prevent or reduce generation of photoelectric current in the active pattern ACT or the like.

The source electrode SD may be located on the substrate SUB. For example, the source electrode SD may be spaced apart from the light blocking layer BML in the first direction DR1. The source electrode SD may be a portion of the first scan line SC1 or the second scan line SC2 of FIG. 2. The source electrode SD may include the same material as the light blocking layer LS and may be formed through the same process as the light blocking layer LS. The source electrode SD may be referred to as a third electrode.

The buffer layer BUF may be located on the substrate SUB. The buffer layer BUF may prevent or reduce diffusion of metal atoms, contaminants, or impurities from the substrate SUB to the transistor TR. In addition, the buffer layer BUF can improve the flatness of a surface of the substrate SUB when the surface of the substrate SUB is not uniform.

For example, the buffer layer BUF may include an inorganic material such as silicon oxide, silicon nitride, silicon oxynitride, and the like. These materials may be used alone or in combination with each other.

The active pattern ACT may be located on the buffer layer BUF. For example, the active pattern ACT may overlap a portion of the first pixel area PX1. The active pattern ACT may include a metal oxide semiconductor, an inorganic semiconductor (e.g., amorphous silicon, polysilicon), or an organic semiconductor. The active pattern ACT may include a source area, a drain area, and a channel area located between the source area and the drain area.

The metal oxide semiconductor may include a binary compound (“ABₓ”), a ternary compound (“ABₓC_{y}”), a tetragonal compound (“ABₓC_{y}D_{z}”), and the like including indium (“In”), zinc (“Zn”), gallium (“Ga”), tin (“Sn”), titanium (“Ti”), aluminum (“Al”), hafnium (“Hf”), zirconium (“Zr”), magnesium (“Mg”), or the like.

For example, the metal oxide semiconductor may include zinc oxide (“ZnOₓ”), gallium oxide (“GaOₓ”), tin oxide (“SnOₓ”), indium oxide (“InOₓ”), indium gallium oxide (“IGO”), indium zinc oxide (“IZO”), indium tin oxide (“ITO”), indium zinc tin oxide (“IZTO”), indium gallium zinc oxide (“IGZO”), or the like. These materials may be used alone or in combination with each other.

The gate insulating layer GI may be located on the active pattern ACT. The gate insulating layer GI may sufficiently cover the active pattern ACT, and may have a substantially flat upper surface without generating a step around the active pattern ACT. Alternatively, the gate insulating layer GI may cover the active pattern ACT and may be arranged along a profile of the active pattern ACT.

For example, the gate insulating layer GI may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and the like. These materials may be used alone or in combination with each other.

The gate electrode GE may be located on the gate insulating layer GI. For example, the gate electrode GE may overlap the first pixel area PX1. The active pattern ACT may be activated based on a signal applied to the gate electrode GE.

The gate electrode GE may include a metal, an alloy metal nitride, a conductive metal oxide, a transparent conductive material, or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other.

Examples of the conductive metal oxide may include Indium tin oxide, indium zinc oxide, or the like. In addition, examples of the metal nitride may include aluminum nitride (“AlNₓ”), tungsten nitride (“WNₓ”), chromium nitride (“CrNₓ”), or the like. Each of these materials may be used alone or in combination with each other.

The gate electrode GE may define a first opening OP1. This may be to prevent or reduce instances of defective signals transmitted through the gate electrode GE being applied to the light emitting element EE when the first pixel area PX1 is a pixel area in which a defect occurs. That is, in this specification, the first pixel area PX1 may be a pixel area in which a defect occurs. For example, through the first opening OP1, the gate electrode GE may be separated into a first portion connected to the pixel electrode PE and a second portion not connected to the pixel electrode PE. For example, the first opening OP1 may be formed in the form of a hole separating the gate electrode GE as described before.

The array test pad ATP may be located on the gate insulating layer GI. For example, the array test pad ATP may overlap the array test area. An upper surface of the array test pad ATP may be exposed through a fifth opening OP5 and a sixth opening OP6 to be described later. The array test pad ATP may include the same material as the gate electrode GE and may be formed through the same process as the gate electrode GE.

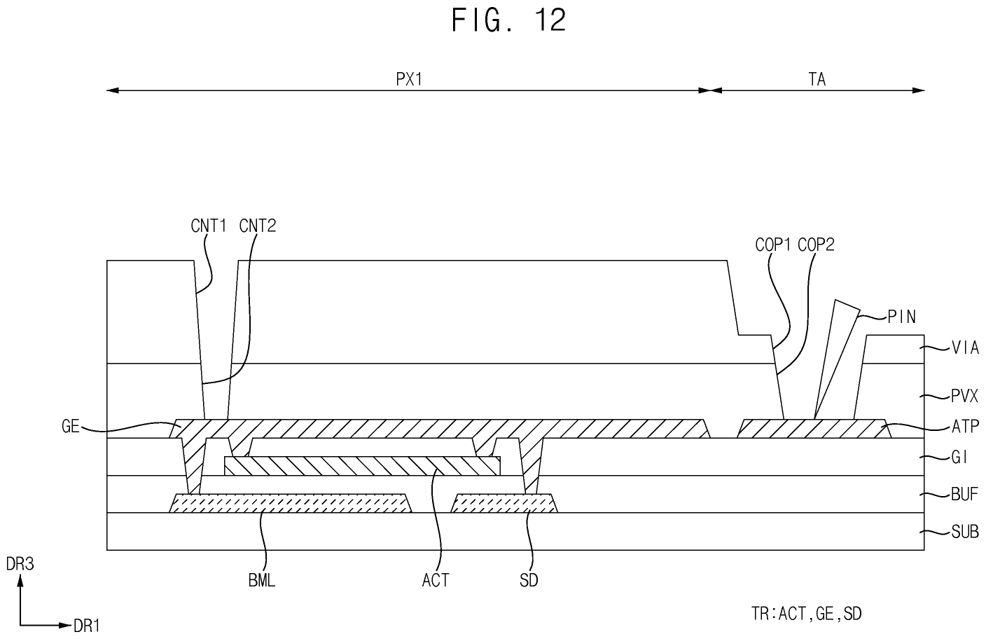

An array test may be performed by contacting a probe pin (e.g., a probe pin PIN of FIG. 12) with the array test pad ATP. The probe pin may apply a test signal to the array test pad ATP. Thereafter, amount of charge stored in the first pixel area PX1 may be detected. Accordingly, the presence of a defect such as a disconnection or a short circuit in the transistor TR may be confirmed.

The passivation layer PVX may be located on the gate electrode GE and the array test pad ATP. The passivation layer PVX may sufficiently cover the gate electrode GE and the array test pad ATP. The passivation layer PVX may protect lower layers including the gate electrode GE and the array test pad ATP.

For example, the passivation layer PVX may include inorganic materials such as silicon oxide (“SiOₓ”), silicon nitride (“SiNₓ”), silicon oxynitride (“SiOₓN_{y}”), or the like. These materials may be used alone or in combination with each other.

The passivation layer PVX may define a second opening OP2. For example, the second opening OP2 may overlap the first opening OP1. In addition, the passivation layer PVX may define the fifth opening OP5. For example, the fifth opening OP5 may overlap the array test area TA.

The via insulating layer VIA may be located on the passivation layer PVX. The via insulating layer VIA may include an organic material. For example, the via insulating layer VIA may include organic materials such as phenolic resin, acrylic resin, polyimide resin, polyamide resin, siloxane resin, epoxy resin, and the like. These materials may be used alone or in combination with each other.

The via insulating layer VIA may define a third opening OP3. For example, the third opening OP3 may overlap the second opening OP2. In addition, the via insulating layer VIA may define a sixth opening OP6. For example, the sixth opening OP6 may overlap the fifth opening OP5.

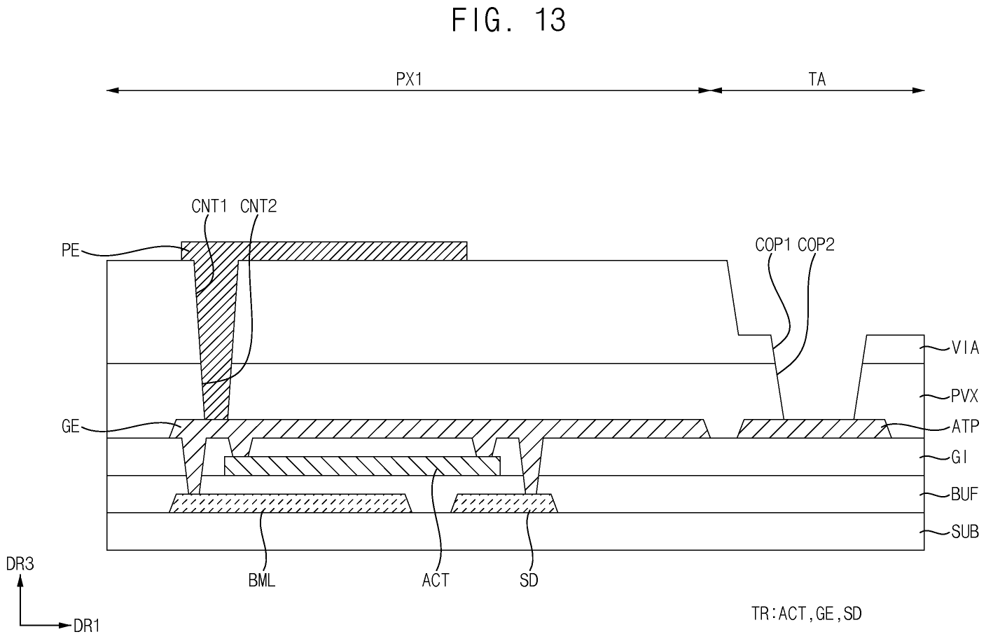

The pixel electrode PE may be located on the passivation layer PVX. For example, the pixel electrode PE may overlap a portion of the first pixel area PX1. The pixel electrode PE may be connected to the gate electrode GE through a first contact portion (e.g., a first contact portion CNT1 of FIG. 13) penetrating the via insulating layer VIA and a second contact portion (e.g., a second contact portion CNT2 of FIG. 13) penetrating the passivation layer PVX.

The pixel electrode PE may include a metal, an alloy, a metal nitride, a conductive metal oxide, a transparent conductive material, and the like. These materials be used alone or in combination with each other. According to some embodiments, the pixel electrode PE may have a stacked structure including ITO/Ag/ITO. For example, the pixel electrode PE may operate as an anode.

According to some embodiments, the pixel electrode PE may define a seventh opening OP7. For example, the seventh opening OP7 may overlap the third opening OP3.

The first opening OP1, the second opening OP2, the third opening OP3, and the seventh opening OP7 may form one through-hole. Through the through-hole, the gate electrode GE may be separated into the first portion connected to the pixel electrode PE and the second portion not connected to the pixel electrode PE.

According to some embodiments, the through-hole may be formed through a laser cutting process.

According to some embodiments, a width of the through-hole in the first direction DR1 may be about 4 micrometers (um) or less. When the width of the through-hole is greater than about 4 micrometers, the insulating layer PL to be described later may not be well formed in the through-hole. This may be because, when the width of the through-hole is greater than about 4 micrometers, a developer used in a photolithography process may penetrate the through-hole.

The pixel defining layer PDL may be located on the via insulating layer VIA. The pixel defining layer PDL may cover side portions of the pixel electrode PE. In addition, the pixel defining layer PDL may expose a portion of an upper surface of the pixel electrode PE.

For example, the pixel defining layer PDL may include an inorganic material or an organic material. According to some embodiments, the pixel defining layer PDL may include an organic material such as an epoxy resin, a siloxane resin, and the like.

These materials may be used alone or in combination with each other. According to some embodiments, the pixel defining layer PDL may further include a light blocking material containing a black pigment, a black dye, or the like.

The insulating layer PL may fill the first opening OP1. According to some embodiments, the insulating layer PL may fill the first opening OP1 and at least a portion of the second opening OP2. According to some embodiments, the insulating layer PL may fill the second opening OP2, and the first opening OP1, and at least a portion of the third opening OP3.

According to some embodiments, the insulating layer PL and the pixel defining layer PDL may include the same material. For example, when the pixel defining layer PDL includes an organic material, the insulating layer PL may also include the organic material. However, embodiments according to the present disclosure are not limited thereto, and according to some embodiments, the insulating layer PL and the pixel defining layer PDL may include different materials.

According to some embodiments, an upper surface of the insulating layer PL may have a convex shape downward in a cross-sectional view. However, embodiments according to the present disclosure are not limited to this, and according to some embodiments, the upper surface of the insulating layer PL may have various forms, such as a convex shape upward in the cross-sectional view.

The light emitting layer EML may be located on the pixel defining layer PDL, the pixel electrode PE, and the insulating layer PL. The light emitting layer EML may extend to the array test pad ATP. For example, a portion overlapping the first pixel area PX1 of the light emitting layer EML may include a hole injection layer, a hole transport layer located on the hole injection layer, an organic layer located on the hole transport layer, an electron transport layer located on the organic layer, and an electron injection layer located on the electron transport layer.

However, embodiments according to the present disclosure are not limited thereto, and a portion overlapping the first pixel area PX1 of the light emitting layer EML may include other components such as an electron blocking layer, a hole blocking layer, or the like.

According to some embodiments, a portion overlapping the array test area TA of the light emitting layer EML may include the same components as the portion overlapping the first pixel area PX1 of the light emitting layer EML. However, embodiments according to the present disclosure are not limited thereto, and according to some embodiments, the portion overlapping the array test area TA of the light emitting layer EML may include the hole injection layer, the hole transport layer located on the hole injection layer, the electron transport layer located on the hole transport layer, and the electron injection layer located on the electron transport layer.

The common electrode CE may be located on the light emitting layer EML. The common electrode CE may extend to the array test pad ATP. The common electrode CE may include a metal, an alloy, a metal nitride, a conductive metal oxide, a transparent conductive material, or the like. These materials may be used alone or in combination with each other.

The insulating layer PL may prevent or reduce instances of a short circuit between the common electrode CE and the gate electrode GE. As mentioned before, the gate electrode GE may define the first opening OP1. The gate electrode GE may be separated into the first portion and the second portion through the first opening OP1. Accordingly, sidewall of each of the first portion and the second portion may be exposed. The insulating layer PL may prevent or reduce instances of the common electrode CE being short-circuited with the sidewall of each of the first portion and the second portion of the gate electrode GE. Accordingly, it may be possible to prevent or reduce instances of a defective signal transmitted through the gate electrode GE being transmitted to the common electrode CE through the sidewall of each of the first portion and the second portion.

In addition, the insulating layer PL may prevent or reduce instances of an etchant used in a dry etching process reaching each of the sidewall of the first portion and the second portion of the gate electrode GE. Accordingly, the insulating layer PL may prevent or reduce corrosion of the gate electrode GE.

As described before, the pixel electrode PE may define the seventh opening OP7. That is, the pixel electrode PE may be separated into a first portion connected to the gate electrode GE and a second portion not connected to the gate electrode GE. Accordingly, each of sidewall of the first portion and the second portion of the pixel electrode PE may be exposed. The insulating layer PL may not fill the seventh opening OP7. Accordingly, each of the sidewall of each of the first portion and the second portion of the pixel electrode PE may be short-circuited with the common electrode CE. As described above, because the gate electrode GE is divided into the first portion and the second portion through the first opening OP1, the defective signal may be prevented from being applied to the pixel electrode PE. Therefore, even if each of the sidewall of the first portion and the second portion of the pixel electrode PE are short-circuited with the common electrode CE, the defect signal may not reach the common electrode CE.

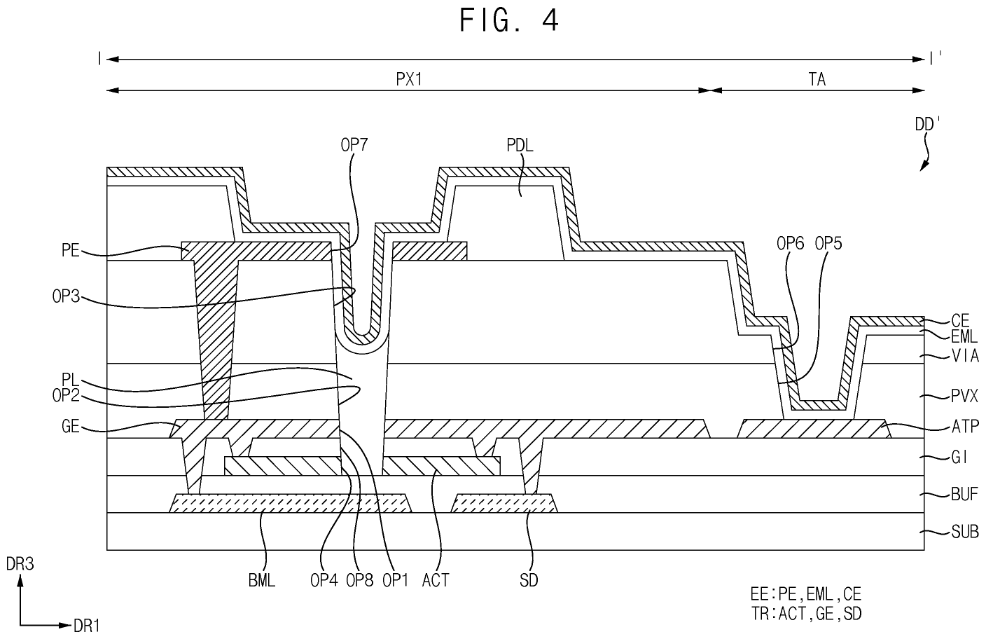

FIG. 4 is a schematic cross-sectional view illustrating a display device according to some embodiments.

In describing a display device DD′ of FIG. 4, the same reference numerals may be assigned to substantially the same components as the display device DD of FIG. 3, and some repetitive detailed description thereof may be omitted.

Referring to FIG. 4, an active pattern ACT of a display device DD′ according to some embodiments may define a fourth opening OP4. For example, the fourth opening OP4 may overlap the first opening OP1. In addition, the gate insulating layer GI may define an eighth opening OP8. For example, the eighth opening OP8 may overlap the fourth opening OP4.

Unlike FIG. 3, the first opening OP1, the second opening OP2, the third opening OP3, the seventh opening OP7, the fourth opening OP4, and the eighth opening OP8 may form one through-hole. In this case, the insulating layer PL may further fill the eighth opening OP8 and the fourth opening OP4.

The active pattern ACT may be separated into a first portion and a second portion like the gate electrode GE. Accordingly, each of sidewall of the first portion and the second portion of the active pattern ACT may be exposed. The insulating layer PL may prevent or reduce instances of each of the sidewall of the first portion and the second portion of the active pattern ACT, as well as each of the sidewall of the first portion and the second portion of the gate electrode GE, being short-circuited with the common electrode CE.

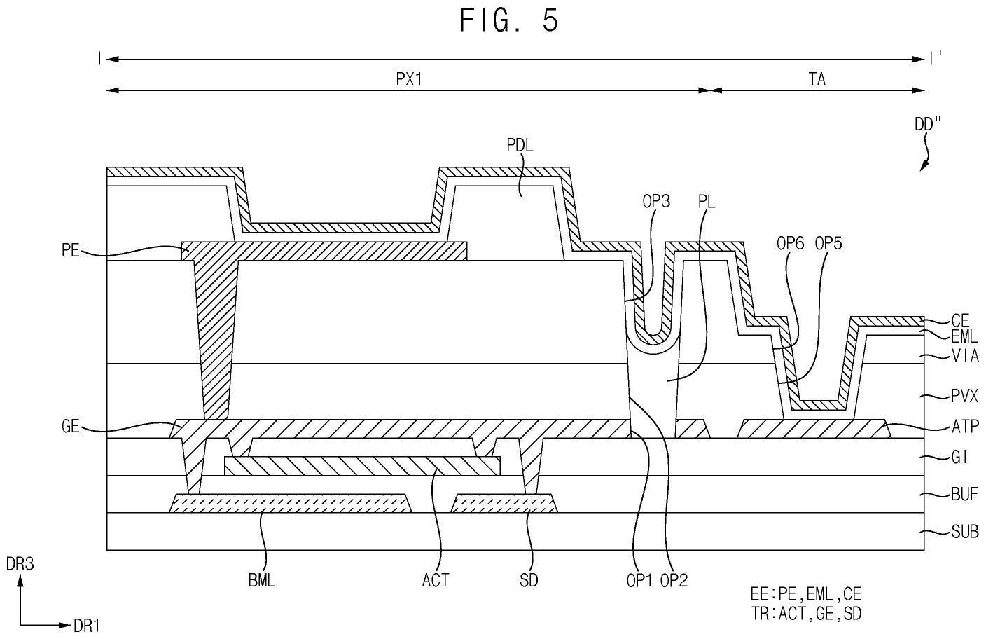

FIG. 5 is a schematic cross-sectional view illustrating a display device according to some embodiments.

In describing a display device DD″ of FIG. 5, the same reference numerals may be assigned to substantially the same components as the display device DD of FIG. 3, and the detailed description thereof may be omitted.

Referring to FIG. 5, a pixel electrode PE of a display device DD′″ according to some embodiments may not define an opening (e.g., the seventh opening OP7 of FIG. 4). In addition, the first opening OP1, the second opening OP2, and the third opening OP3 may not overlap the pixel electrode PE. For example, the first opening OP1, the second opening OP2, and the third opening OP3 may form one through-hole. The through-hole may be spaced apart from the pixel electrode PE in the first direction DR1.

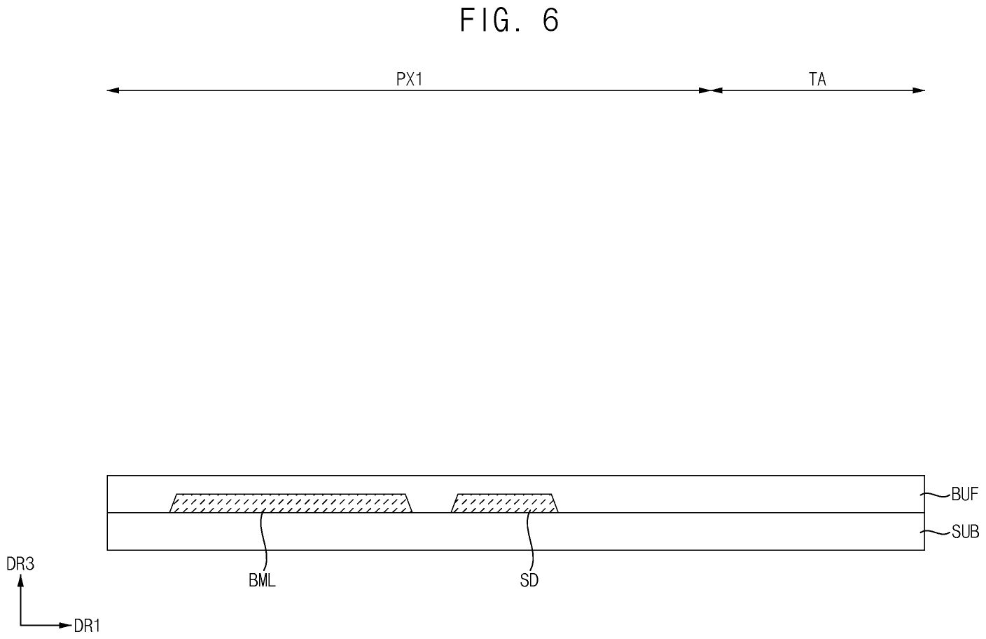

FIGS. 6, 7, 8, 9, 10, 11, 12, 13, 14, 15, and 16 are schematic cross-sectional views illustrating a method of repairing a display device according to some embodiments.

Referring to FIG. 6, the light blocking layer BML may be formed on the substrate SUB. For example, the light blocking layer BML may overlap the first pixel area PX1. In addition, the source electrode SD may be formed on the substrate SUB. For example, the source electrode SD may be formed to be spaced apart from the light blocking layer BML in the first direction DR1. The source electrode SD may include the same material as the light blocking layer LS and may be formed through the same process as the light blocking layer LS.

The buffer layer BUF may be formed on the substrate SUB. For example, the buffer layer BUF may be formed of an inorganic material such as silicon oxide, silicon nitride, silicon oxynitride, or the like. These materials may be used alone or in combination with each other.

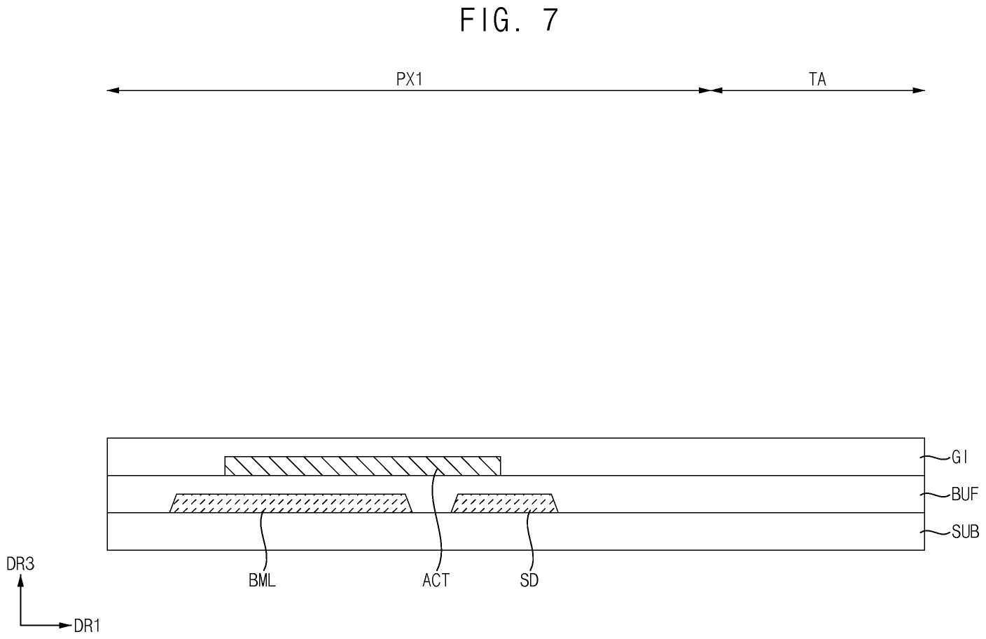

Referring to FIG. 7, the active pattern ACT may be formed on the buffer layer BUF. For example, the active pattern ACT may overlap a portion of the first pixel area PX1. The active pattern ACT may be formed of a metal oxide semiconductor, an inorganic semiconductor (e.g., amorphous silicon, polysilicon), an organic semiconductor, or the like.

The gate insulating layer GI may be formed on the buffer layer BUF. For example, the gate insulating layer GI may be formed of inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), or the like. These materials may be used alone or in combination with each other.

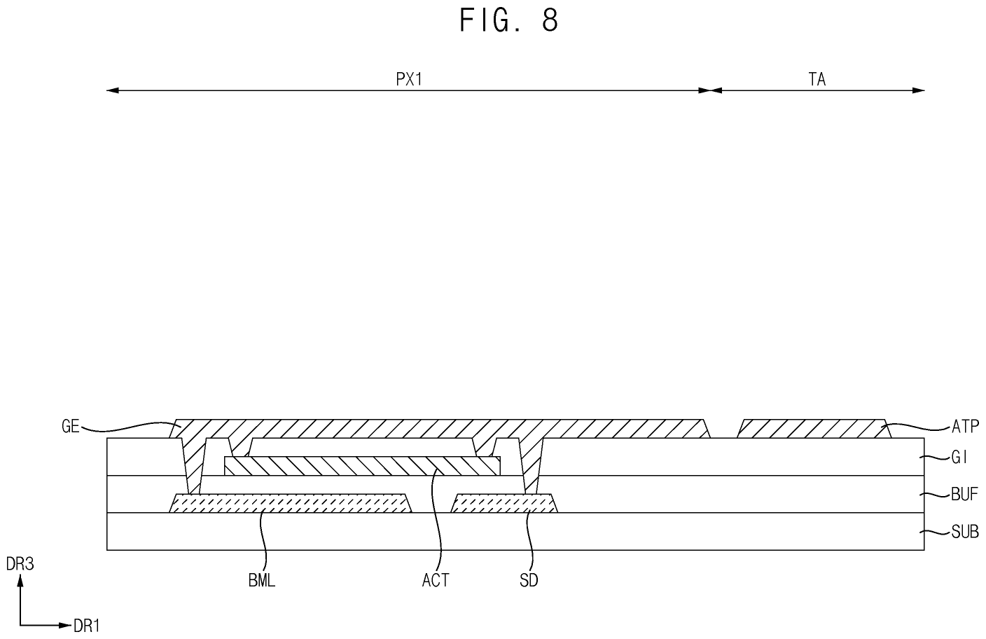

Referring to FIG. 8, the gate electrode GE may be formed on the gate insulating layer GI. For example, the gate electrode GE may overlap the first pixel area PX1. The gate electrode GE may be formed of a metal, an alloy metal nitride, a conductive metal oxide, a transparent conductive material, or the like.

The array test pad ATP may be formed on the gate insulating layer GI. For example, the array test pad ATP may overlap the array test area TA. That is, the array test pad ATP may be formed to be spaced apart from the gate electrode GE in the first direction DR1. The array test pad ATP may include the same material as the gate electrode GE and may be formed through the same process as the gate electrode GE.

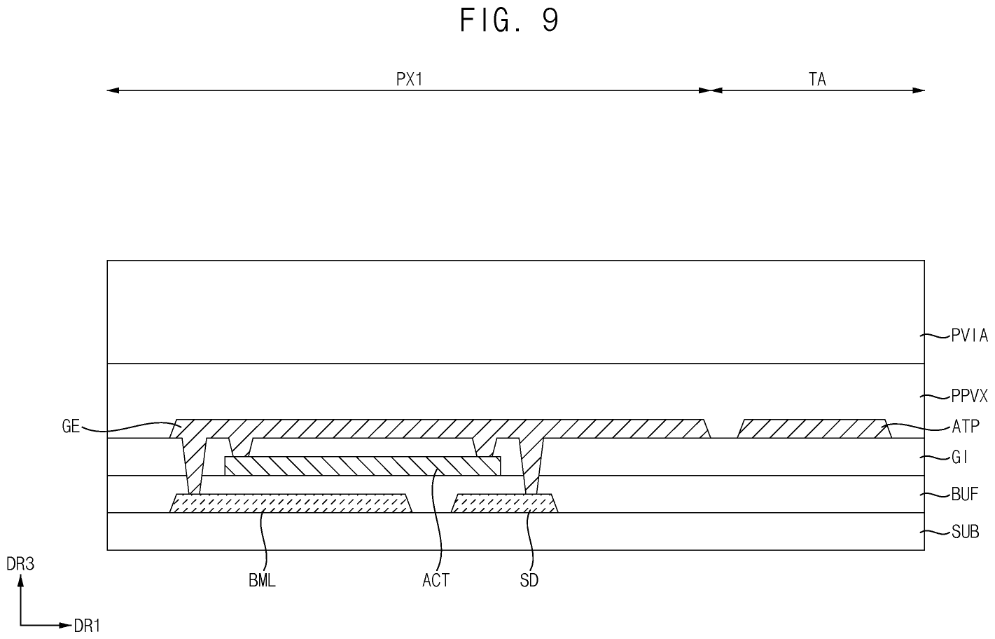

Referring to FIG. 9, a preliminary passivation layer PPVX may be formed on the gate electrode GE and the array test pad ATP. For example, the preliminary passivation layer PPVX may be formed of silicon oxide silicon oxide (“SiOₓ”), (“SiNₓ”), silicon oxynitride (“SiOₓN_{y}”), or the like. These materials may be used alone or in combination with each other.

A preliminary via insulating layer PVIA may be formed on the preliminary passivation layer PPVX. For example, the preliminary via insulating layer PVIA may be formed of organic materials such as phenolic resin, acrylic resin, polyimide resin, polyamide resin, siloxane resin, epoxy resin. or the like. These materials may be used alone or in combination with each other.

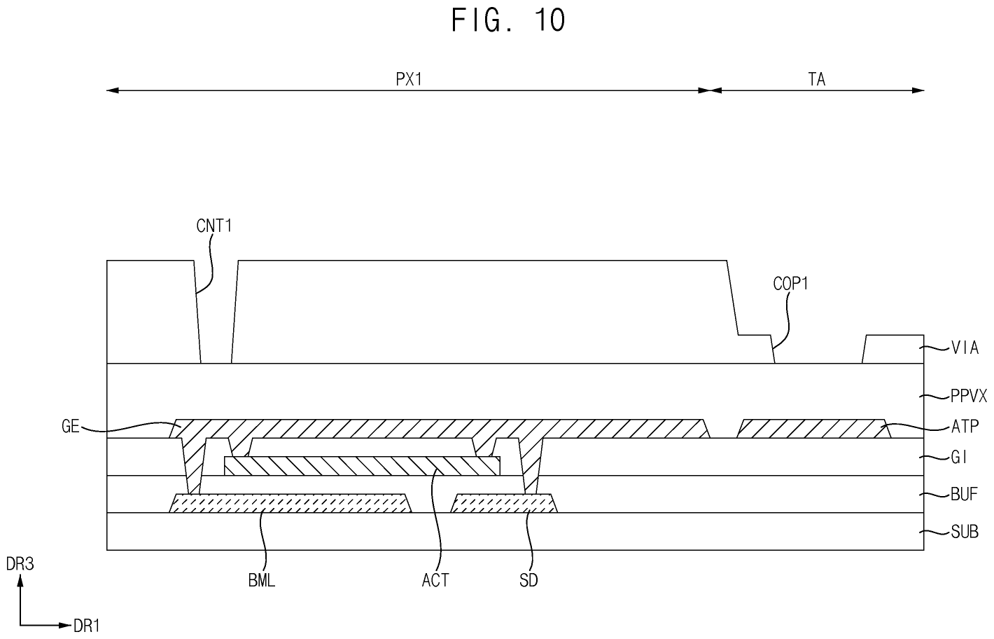

Referring to FIGS. 9 and 10, a first contact portion CNT1 may be formed by removing a portion of the preliminary via insulating layer PVIA. For example, the first contact portion CNT1 may overlap a portion of the first pixel area PX1. In addition, a first cutout portion COP1 may be formed by removing a portion of the preliminary via insulating layer PVIA. For example, the first cutout portion COP1 may overlap the array test area TA. Accordingly, the via insulating layer VIA may be formed.

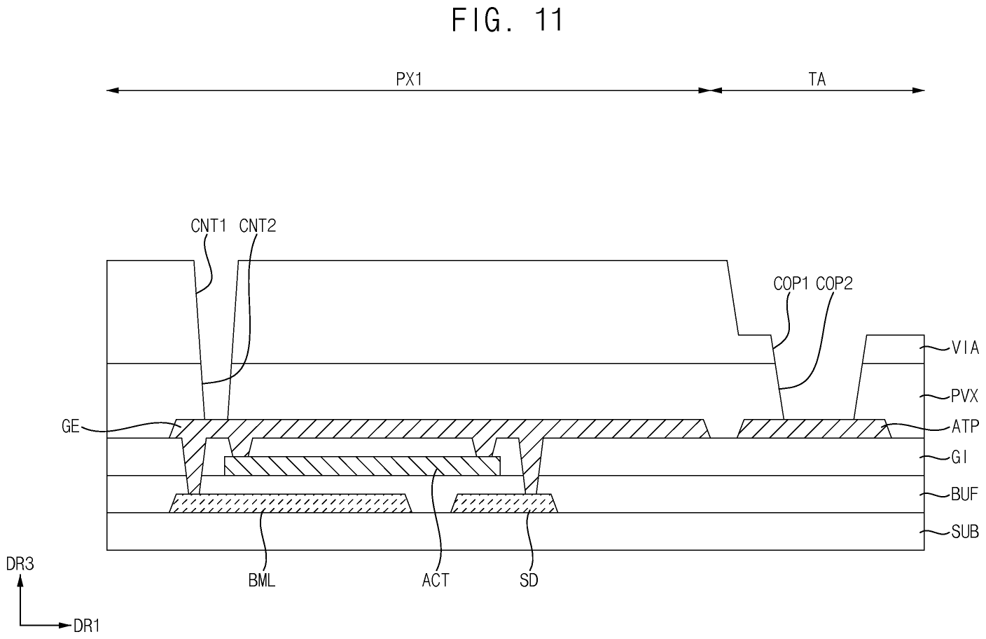

Referring to FIGS. 10 and 11, a second contact portion CNT2 may be formed by removing a portion of the preliminary passivation layer PPVX. For example, the second contact portion CNT2 may overlap the first contact portion CNT1. In addition, a second cutout portion COP2 may be formed by removing a portion of the preliminary passivation layer PPVX. For example, the second cutout portion COP2 may overlap the first cutout portion COP1. Accordingly, the passivation layer PVX may be formed.

The first contact portion CNT1 and the second contact portion CNT2 may expose at least a portion of an upper surface of the gate electrode GE. In addition, the first cutout portion COP1 and the second cutout portion COP2 may expose at least a portion of an upper surface of the array test pad ATP.

Referring to FIG. 12, a probe pin PIN may be in contact with the array test pad ATP. The probe pin PIN may apply a test signal to the array test pad ATP.

Thereafter, amount of charge stored in the first pixel area PX1 may be detected. Accordingly, presence of a defect such as a disconnection or a short circuit in the transistor TR may be confirmed.

Hereinafter, it is assumed that the transistor TR is defective. That is, it is assumed that the first pixel area PX1.

Referring to FIG. 13, the pixel electrode PE may be formed on the via insulating layer VIA. For example, the pixel electrode PE may overlap a portion of the first pixel area PX1. The pixel electrode PE may be formed of a metal, an alloy, a metal nitride, a conductive metal oxide, a transparent conductive material, or the like. These materials may be used alone or in combination with each other. The pixel electrode PE may be connected to the gate electrode GE through the first contact portion CNT1 and the second contact portion CNT2.s a defective pixel area.

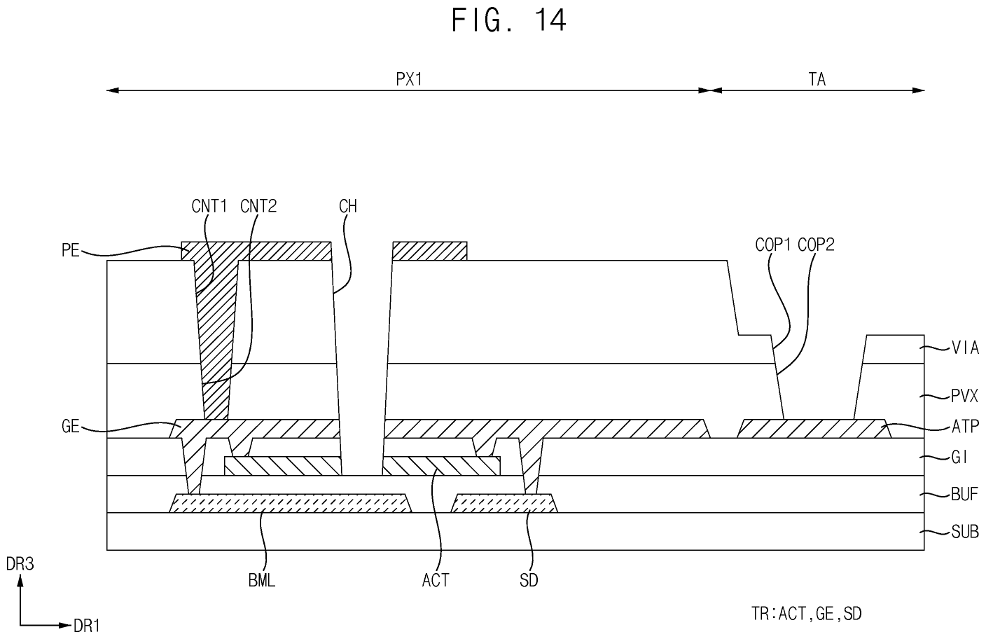

Referring to FIG. 14, a through-hole CH penetrating the active pattern ACT, the gate insulating layer GI, the gate electrode GE, the passivation layer PVX, the via insulating layer VIA, and the pixel electrode PE may be formed. According to some embodiments, the through-hole CH may be formed through a laser cutting process.

However, embodiments according to the present disclosure are not limited thereto, and the through-hole CH may penetrate the gate electrode GE, the passivation layer PVX, and the via insulating layer VIA as illustrated in FIG. 3.

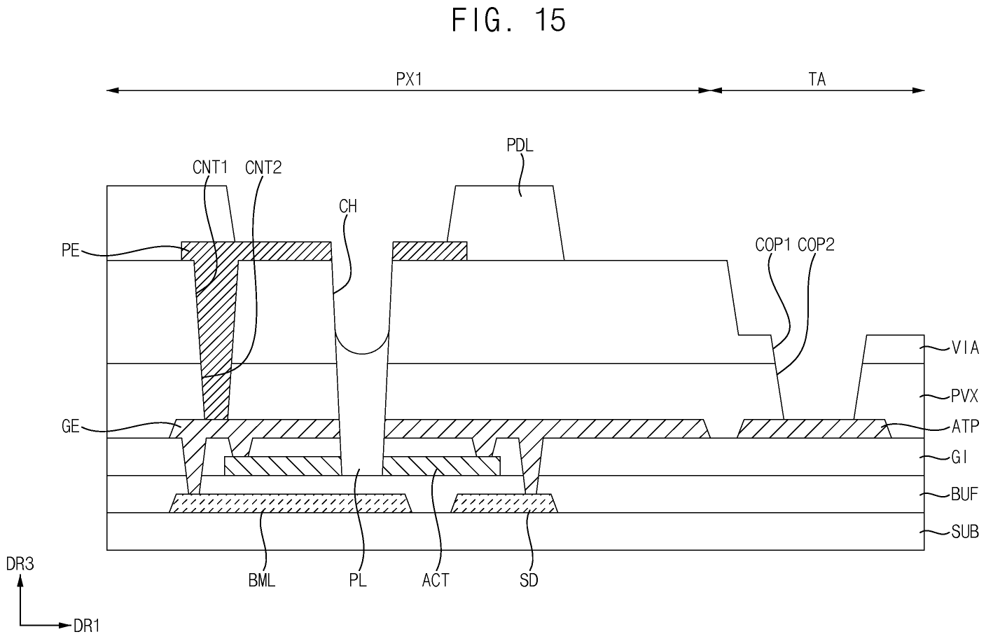

Referring to FIG. 15, the pixel defining layer PDL may be formed on the via insulating layer VIA. The pixel defining layer PDL may cover side portions of the pixel electrode PE and may expose at least a portion of an upper surface of the pixel electrode PE. For example, the pixel defining layer PDL may be formed of an inorganic material or an organic material. According to some embodiments, the pixel defining layer PDL may be formed of an organic material such as an epoxy resin or a siloxane resin. These materials may be used alone or in combination with each other. According to some embodiments, the pixel defining layer PDL may be formed of a light blocking material containing a black pigment, a black dye, or the like.

The insulating layer PL may fill at least a portion of the through-hole CH. According to some embodiments, the insulating layer PL and the pixel defining layer PDL may include the same material. For example, when the pixel defining layer PDL includes an organic material, the insulating layer PL may also include the organic material. In this case, the insulating layer PL and the pixel defining layer PDL may be simultaneously formed through the same process. However, embodiments according to the present disclosure are not limited thereto, and according to some embodiments, the insulating layer PL and the pixel defining layer PLD may include different materials.

According to some embodiments, an upper surface of the insulating layer PL may have a convex shape downward in a cross-sectional view. However, embodiments according to the present disclosure are not limited thereto, and according to some embodiments, the upper surface of the insulating layer PL may have various forms, such as a convex shape upward in the cross-sectional view.

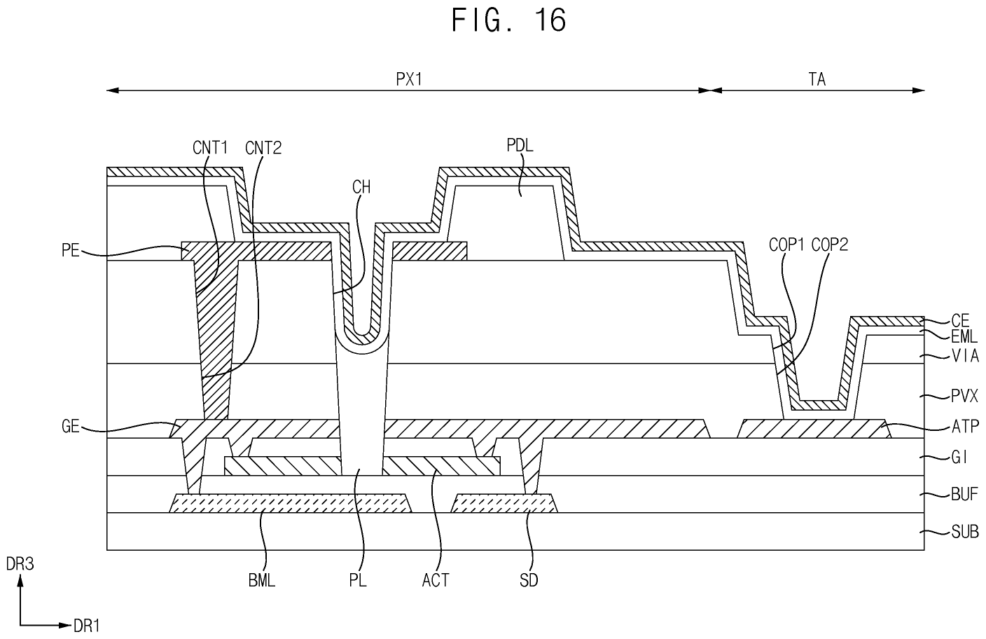

Referring to FIG. 16, the light emitting layer EML may be formed on the pixel defining layer PDL, the pixel electrode PE, and the insulating layer PL. The light emitting layer EML may extend to the array test pad ATP.

The common electrode CE may be formed on the light emitting layer EML. The common electrode CE may extend to the array test pad ATP. The common electrode CE may be formed of a metal, an alloy, a metal nitride, a conductive metal oxide, a transparent conductive material, or the like. These materials may be used alone or in combination with each other.

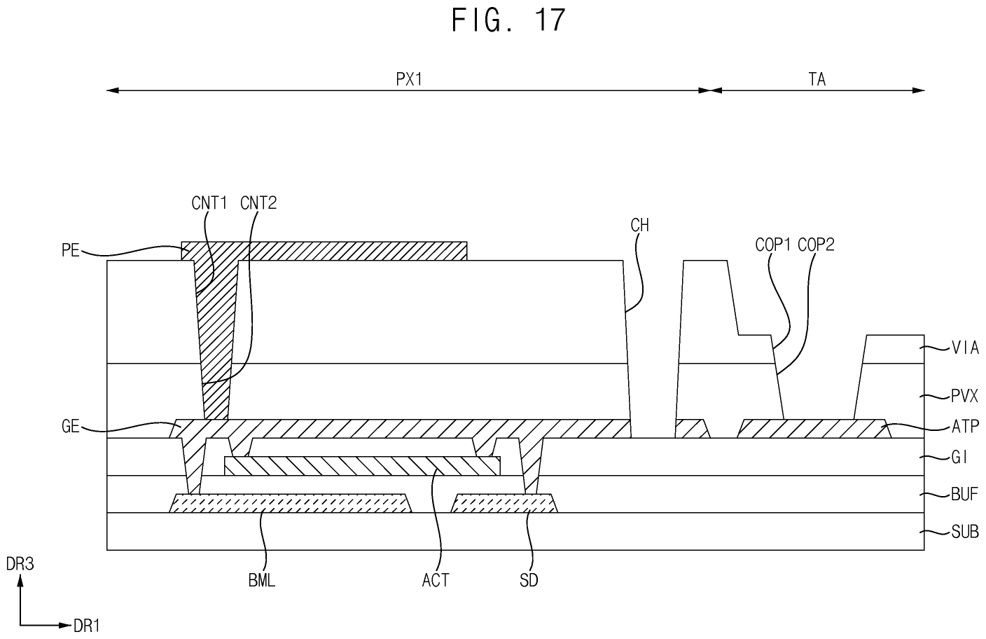

FIGS. 17, 18, and 19 are schematic cross-sectional views illustrating a method of repairing a display device according to some embodiments.

In a method of repairing a display device according to some embodiments as described with respect to FIGS. 17, 18, and 19, substantially the same step as the step included in the method of repairing a display device according to some embodiments as described with respect to FIGS. 6, 7, 8, 9, 10, 11, 12, 13, 14,15, and 16 may be omitted.

Referring to FIG. 17, a through-hole CH penetrating the gate electrode GE, the passivation layer PVX, and the via insulating layer VIA may be formed. The through-hole CH may not overlap the pixel electrode PE. That is, the through-hole CH may be formed to be spaced apart from the pixel electrode PE in the first direction DR1.

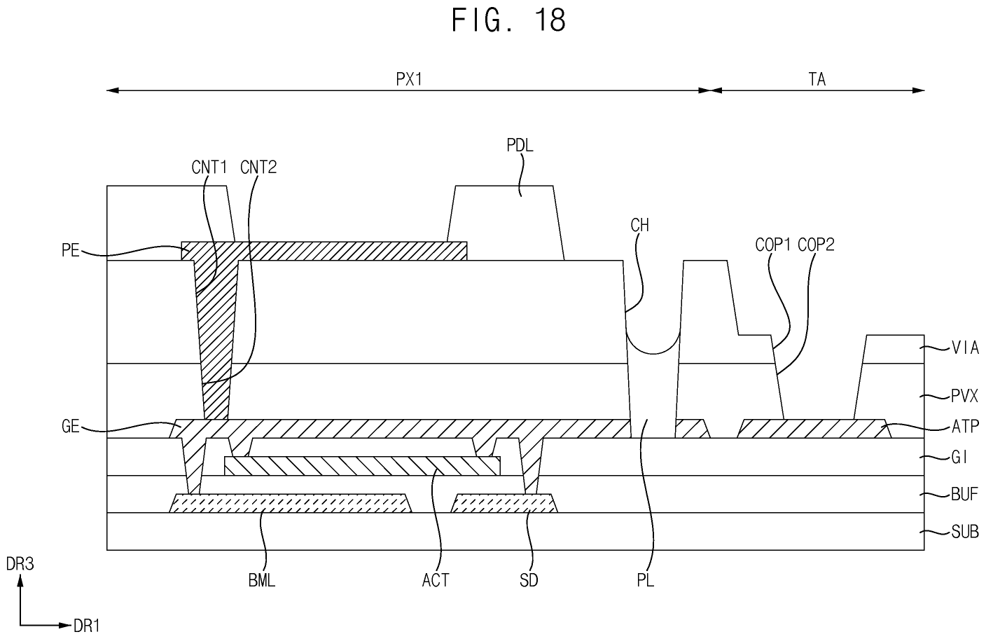

Referring to FIG. 18, the pixel defining layer PDL may be formed on the via insulating layer VIA. The pixel defining layer PDL may cover side portions of the pixel electrode PE and may expose at least a portion of an upper surface of the pixel electrode PE.

The insulating layer PL may fill at least a portion of the through-hole CH. According to some embodiments, the insulating layer PL and the pixel defining layer PDL may include the same material. For example, when the pixel defining layer PDL includes an organic material, the insulating layer PL may also include the organic material. In this case, the insulating layer PL and the pixel defining layer PDL may be simultaneously formed through the same process. However, embodiments according to the present disclosure are not limited thereto, and according to some embodiments, the insulating layer PL and the pixel defining layer PLD may include different materials.

According to some embodiments, an upper surface of the insulating layer PL may have a convex shape downward in a cross-sectional view. However, embodiments according to the present disclosure are not limited thereto, and according to some embodiments, the upper surface of the insulating layer PL may have various forms, such as a convex shape upward in the cross-sectional view.

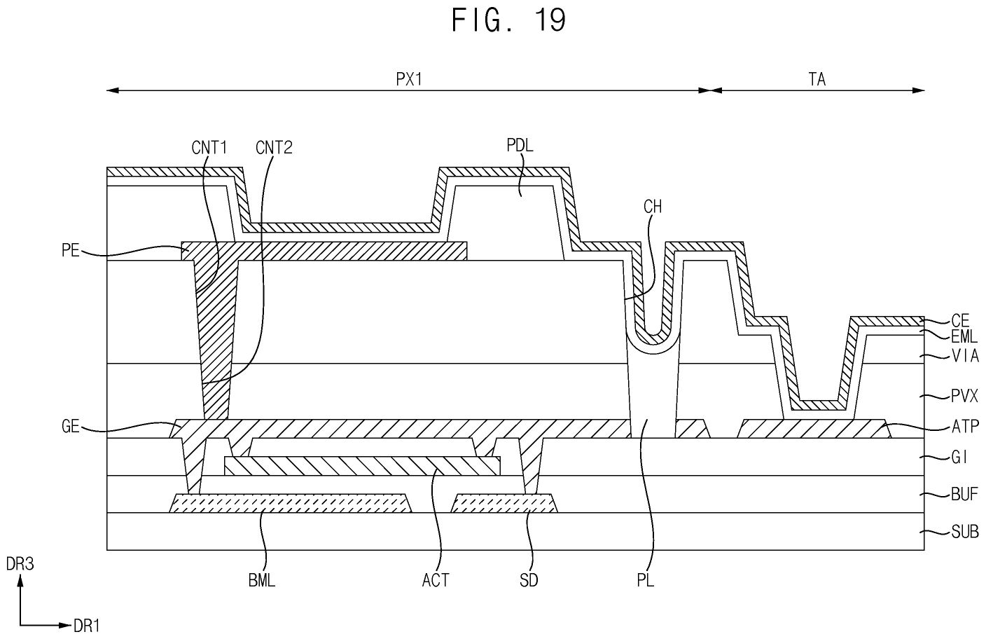

Referring to FIG. 19, the light emitting layer EML may be formed on the pixel defining layer PDL, the pixel electrode PE, and the insulating layer PL. The light emitting layer EML may extend to the array test pad ATP. The common electrode CE may be formed on the light emitting layer EML. The common electrode CE may extend to the array test pad ATP.

The present disclosure can be applied to various display devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present disclosure. Accordingly, all such modifications are intended to be included within the scope of embodiments according to the present disclosure as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims, and their equivalents.

What is claimed is:

1. A display device comprising:
a substrate including a pixel area and an array test area spaced apart from the pixel area;
a gate electrode on the substrate, overlapping the pixel area, and defining a first opening;
a passivation layer on the gate electrode and defining a second opening overlapping the first opening;
a via insulating layer on the passivation layer and defining a third opening overlapping the second opening;
a first electrode on the passivation layer and overlapping a portion of the pixel area; and
an insulating layer filling the first opening.

2. The display device of claim 1, wherein the insulating layer further fills at least a portion of the second opening.

3. The display device of claim 1, wherein the insulating layer further fills the second opening and at least a portion of the third opening.

4. The display device of claim 1, further comprising:
a pixel defining layer covering side portions of the first electrode and exposing an upper surface of the first electrode,
wherein the insulating layer and the pixel defining layer include a same material.

5. The display device of claim 4, wherein the insulating layer and the pixel defining layer include an organic material.

6. The display device of claim 1, further comprising:
an active pattern between the substrate and the gate electrode,
wherein the active pattern defines a fourth opening overlapping the first opening and the insulating layer further fills the fourth opening.

7. The display device of claim 1, further comprising:
an array test pad on the substrate and overlapping the array test area.

8. The display device of claim 7, wherein the passivation layer defines a fifth opening overlapping the array test area.

9. The display device of claim 8, wherein the via insulating layer defines a sixth opening overlapping the fifth opening.

10. The display device of claim 9, wherein a portion of an upper surface of the array test pad is exposed through the fifth opening and the sixth opening.

11. The display device of claim 1, wherein the first electrode defines a seventh opening overlapping the third opening.

12. The display device of claim 1, further comprising:
a light emitting layer on the first electrode and the insulating layer; and
a second electrode on the light emitting layer.

13. The display device of claim 1, further comprising:
a light blocking layer between the substrate and the gate electrode, and the light blocking layer connected to the gate electrode.

14. The display device of claim 13, further comprising:
a third electrode between the substrate and the gate electrode, spaced apart from the light blocking layer in a first direction, and connected to the gate electrode.

15. A method of repairing a display device, the method comprising:
forming an active pattern on a substrate and overlapping a portion of a pixel area;
forming a gate electrode on the active pattern and overlapping the pixel area and an array test pad spaced apart from the gate electrode in a first direction;
forming a preliminary passivation layer on the gate electrode and the array test pad;
forming a preliminary via insulating layer on the preliminary passivation layer;
forming a via insulating layer defining a first contact portion overlapping a portion of the pixel area and a first cutout portion overlapping the array test area by removing a portion of the preliminary via insulating layer;
forming a passivation layer defining a second contact portion overlapping the first contact portion and a second cutout portion overlapping the first cutout portion by removing a portion of the preliminary passivation layer;
contacting a probe pin with the array test pad;
forming a through-hole penetrating the via insulating layer, the passivation layer, and the gate electrode; and
forming an insulating layer filling at least a portion of the through-hole.

16. The method of claim 15, wherein the first cutout portion and the second cutout portion expose an upper surface of the array test pad.

17. The method of claim 15, further comprising:
forming a first electrode on the via insulating layer and overlapping a portion of the pixel area after the contacting the probe pin with the array test pad and before the forming the through-hole penetrating the via insulating layer, the passivation layer, and the gate electrode.

18. The method of claim 17, wherein the first electrode and the gate electrode are connected through the first contact portion and the second contact portion.

19. The method of claim 17, further comprising:
forming a pixel defining layer covering side portions of the first electrode and exposing an upper surface of the first electrode after the forming the through-hole penetrating the via insulating layer, the passivation layer, and the gate electrode,
wherein the forming an insulating layer filling at least a portion of the through-hole is performed simultaneously with the forming the pixel defining layer.

20. The method of claim 17, wherein the forming the through-hole further includes penetrating the first electrode.
